(19) United States
(12) Patent Application Publication
(10) Pub. No.: US 2022/0108197 A1
(43) Pub. Date: Apr. 7, 2022

(54) SYSTEMS AND METHODS FOR ERROR DETECTION, REMEDIATION, AND INTEGRITY SCORING OF DIRECTED ACYCLIC GRAPHS

(71) Applicant: Moovila, Inc., Mount Pleasant, SC (US)

(72) Inventors: Michael J. Psenka, Sullivans Island, SC (US); Michael P. Psenka, Sullivans Island, SC (US)

(21) Appl. No.: 17/496,689

(22) Filed: Oct. 7, 2021

Related U.S. Application Data
(60) Provisional application No. 63/088,949, filed on Oct. 7, 2020.

(51) Int. Cl. G06N 7/00; G06F 9/38

(52) U.S. Cl. CPC G06N 7/005; G06F 9/3838

(57) ABSTRACT

Systems and methods for error detection, remediation, and integrity scoring of directed acyclic graphs are disclosed. According to an aspect, a method includes providing, in the memory, a directed acyclic graph including a plurality of vertices and a plurality of edges connecting the vertices. The vertices represent tasks in a project. The edges represent dependencies among the tasks. The method also includes providing, for each vertex, at least one task property capable of affecting a property of one of the vertex's successor vertices via an edge. Further, the method includes analyzing one or more properties of the vertices and the edge dependencies to characterize the task properties. The method also includes presenting the analysis via a user interface.

### CROSS REFERENCE TO RELATED APPLICATION

This application claims priority to U.S. Provisional Patent Application No. 63/088,949, filed Oct. 7, 2020, and titled “Methods and Systems for Automated Error Detection, Remediation and Integrity Scoring of Directed Acyclic Graphs”, the content of which is incorporated herein by reference in its entirety.

### TECHNICAL FIELD

The presently disclosed subject matter relates generally to project management analysis and reporting. Particularly, the presently disclosed subject matter relates to systems and methods for error detection, remediation, and integrity scoring of directed acyclic graphs.

### BACKGROUND

In the discrete mathematics field of graph theory and in computer science, directed acyclic graphs (DAG) are logical and data representations consisting of vertices and edges. The vertices are connected via edges. These graphs are constructed so no sequence of connections results in a loop within the graph. DAGs are used in a wide variety of applications. DAGs can be topologically sorted to determine longest and shortest paths to solve problems in fields of project management and others. When DAGs are used in the project management embodiment, individual vertices (tasks), carry a wide variety of properties (e.g. start and due dates, task resource, duration, work requirements, etc.). These vertices (tasks) are related to each other via edges (task dependencies). The properties on these vertices (tasks) and relationships can be improperly structured, absent, or updated after initial construction, and produce non-obvious integrity flaws to the creators and participants. The result of these flaws is a project plan with inaccurate dates, completion timelines and resource requirements.

With the rapid increase of connectivity, internet of things (IoT) and collaboration, DAG integrity, in the use case of project management, utilizing a significant number of resources, quickly becomes degraded over time. Manual investigation of DAG, in the case of the project management embodiment, the project plan, is an incredibly time-consuming process and impractical on anything but the smallest DAGs. The lack of continual detection and remediation generates significant risk due to inaccuracies around forecasts and resource constraints within this embodiment.

In view of the foregoing, there is a continuing need for improved systems and techniques for project management analysis and reporting.

### BRIEF DESCRIPTION OF THE DRAWINGS

Having thus described the presently disclosed subject matter in general terms, reference will now be made to the accompanying Drawings, which are not necessarily drawn to scale, and wherein:

FIG. 1 is a block diagram of system including a computing device configured to provide a DAG representative of a project for management, to analyze properties of the DAG, and to present the analysis via a user interface in accordance with embodiments of the present disclosure;

FIG. 2 is a flow diagram of a method for providing a DAG representative of a project for management, analyzing properties of the DAG, and presenting the analysis via a user interface in accordance with embodiments of the present disclosure;

FIG. 3 is a schematic diagram of a DAG in the field of project management in accordance with embodiments of the present disclosure;

FIG. 4 is a flow diagram of a method for continuous identification of structural errors and deficiencies in sub-second performance for DAGs with a high plurality of vertices (tasks) and edges (dependency relationships);

FIG. 5 is a schematic diagram of a DAG showing a mathematically inaccurate property within the DAG;

FIG. 6 is a schematic diagram of a DAG showing fragmentation within the DAG. In the field of project management, fragmentation is typically an indication of incomplete DAG definition;

FIG. 7 is a schematic diagram of a DAG showing an illogical property value within the DAG;

FIG. 8 is a schematic diagram of a DAG with a missing required property for the DAG definition;

FIG. 9 is a schematic diagram of a DAG with an inaccurate immutable property within the DAG definition;

FIG. 10 is a schematic diagram of a DAG with a property constraint violation within the DAG definition;

FIG. 11 is a schematic diagram of a DAG with a vertex property with a value that exceeds best practice for the type of DAG use case;

FIG. 12 is a schematic diagram of a DAG with increased probabilistic risk based on statistical modeling of the relationships between vertices within the DAG;

FIG. 13 is a schematic diagram of a flawed DAG within the project management embodiment;

FIG. 14 is a graph with a sigmoid, or logistic growth curve, representing non-linear response to a component penalty associated with logic flaws, absent properties, resource constraints and probabilistic risk within a DAG;

FIG. 15 is a graph with a composite, nonlinear decay function to describe the degradation of the graph integrity index (y axis) from a maximum score and an asymptotic approach to a pre-defined floor value;

FIG. 16 is a diagram of a computer-agent-directed remediation of a DAG for one or more logic flaws it may contain;

FIG. 17 is a diagram representing multi-stage, dynamic identification and display of one or more areas of interest within a DAG;

FIG. 18 is a diagram depicting edge types within the DAG for the project management embodiment.

FIG. 19 is a diagram depicting transitive reduction of a DAG; and

FIG. 20 is a diagram depicting Current Property Values (CPV), Logical Property Values (LPV) and property constraint impacts on a DAG in the project management embodiment.

### SUMMARY

The presently disclosed subject matter is directed to systems and methods for error detection, remediation, and integrity scoring of directed acyclic graphs. According to an aspect, a method includes providing, in the memory, a directed acyclic graph including a plurality of vertices and a plurality of edges connecting the vertices. The vertices represent tasks in a project. The edges represent dependencies among the tasks. The method also includes providing, for each vertex, at least one task property capable of affecting a property of one of the vertex's successor vertices via an edge. Further, the method includes analyzing one or more properties of the vertices and the edge dependencies to characterize the task properties. The method also includes presenting the analysis via a user interface.

### DETAILED DESCRIPTION

The following detailed description is made with reference to the figures. Exemplary embodiments are described to illustrate the disclosure, not to limit its scope, which is defined by the claims. Those of ordinary skill in the art will recognize a number of equivalent variations in the description that follows.

Articles “a” and “an” are used herein to refer to one or to more than one (i.e. at least one) of the grammatical object of the article. By way of example, “an element” means at least one element and can include more than one element.

“About” is used to provide flexibility to a numerical endpoint by providing that a given value may be “slightly above” or “slightly below” the endpoint without affecting the desired result.

The use herein of the terms “including,” “comprising,” or “having,” and variations thereof is meant to encompass the elements listed thereafter and equivalents thereof as well as additional elements. Embodiments recited as “including,” “comprising,” or “having” certain elements are also contemplated as “consisting essentially of” and “consisting” of those certain elements.

Unless otherwise defined, all technical terms used herein have the same meaning as commonly understood by one of ordinary skill in the art to which this disclosure belongs.

The functional units described in this specification have been labeled as computing devices. A computing device may be implemented in programmable hardware devices such as processors, digital signal processors, central processing units, field programmable gate arrays, programmable array logic, programmable logic devices, cloud processing systems, or the like. The computing devices may also be implemented in software for execution by various types of processors. An identified device may include executable code and may, for instance, comprise one or more physical or logical blocks of computer instructions, which may, for instance, be organized as an object, procedure, function, or other construct. Nevertheless, the executable of an identified device need not be physically located together but may comprise disparate instructions stored in different locations which, when joined logically together, comprise the computing device and achieve the stated purpose of the computing device. In another example, a computing device may be a server or other computer located within a retail environment and communicatively connected to other computing devices (e.g., POS equipment or computers) for managing accounting, purchase transactions, and other processes within the retail environment. In another example, a computing device may be a mobile computing device such as, for example, but not limited to, a smart phone, a cell phone, a pager, a personal digital assistant (PDA), a mobile computer with a smart phone client, or the like. In another example, a computing device may be any type of wearable computer, such as a computer with a head-mounted display (HMD), or a smart watch or some other wearable smart device. Some of the computer sensing may be part of the fabric of the clothes the user is wearing. A computing device can also include any type of conventional computer, for example, a laptop computer or a tablet computer. A typical mobile computing device is a wireless data access-enabled device (e.g., an iPHONE® smart phone, a NEXUS ONE™ smart phone, an iPAD® device, smart watch, or the like) that is capable of sending and receiving data in a wireless manner using protocols like the Internet Protocol, or IP, and the wireless application protocol, or WAP. This allows users to access information via wireless devices, such as smart watches, smart phones, mobile phones, pagers, two-way radios, communicators, and the like. Wireless data access is supported by many wireless networks, including, but not limited to, Bluetooth, Near Field Communication, CDPD, CDMA, GSM, PDC, PHS, TDMA, FLEX, ReFLEX, iDEN, TETRA, DECT, DataTAC, Mobitex, EDGE and other 2G, 3G, 4G, 5G, and LTE technologies, and it operates with many handheld device operating systems, such as PalmOS, EPOC, Windows CE, FLEXOS, OS/9, JavaOS, iOS and Android. Typically, these devices use graphical displays and can access the Internet (or other communications network) on so-called mini- or micro-browsers, which are web browsers with small file sizes that can accommodate the reduced memory constraints of wireless networks. In a representative embodiment, the mobile device is a cellular telephone or smart phone or smart watch that operates over GPRS (General Packet Radio Services), which is a data technology for GSM networks or operates over Near Field Communication e.g. Bluetooth. In addition to a conventional voice communication, a given mobile device can communicate with another such device via many different types of message transfer techniques, including Bluetooth, Near Field Communication, SMS (short message service), enhanced SMS (EMS), multi-media message (MMS), email WAP, paging, or other known or later-developed wireless data formats. Although many of the examples provided herein are implemented on smart phones, the examples may similarly be implemented on any suitable computing device, such as a computer.

An executable code of a computing device may be a single instruction, or many instructions, and may even be distributed over several different code segments, among different applications, and across several memory devices. Similarly, operational data may be identified and illustrated herein within the computing device, and may be embodied in any suitable form and organized within any suitable type of data structure. The operational data may be collected as a single data set, or may be distributed over different locations including over different storage devices, and may exist, at least partially, as electronic signals on a system or network.

The described features, structures, or characteristics may be combined in any suitable manner in one or more embodiments. In the following description, numerous specific details are provided, to provide a thorough understanding of embodiments of the disclosed subject matter. One skilled in the relevant art will recognize, however, that the disclosed subject matter can be practiced without one or more of the specific details, or with other methods, components, materials, etc. In other instances, well-known structures, materials, or operations are not shown or described in detail to avoid obscuring aspects of the disclosed subject matter.

As used herein, the term “memory” is generally a storage device of a computing device. Examples include, but are not limited to, read-only memory (ROM) and random access memory (RAM).

The device or system for performing one or more operations on a memory of a computing device may be a software, hardware, firmware, or combination of these. The device or the system is further intended to include or otherwise cover all software or computer programs capable of performing the various heretofore-disclosed determinations, calculations, or the like for the disclosed purposes. For example, exemplary embodiments are intended to cover all software or computer programs capable of enabling processors to implement the disclosed processes. Exemplary embodiments are also intended to cover any and all currently known, related art or later developed non-transitory recording or storage mediums (such as a CD-ROM, DVD-ROM, hard drive, RAM, ROM, floppy disc, magnetic tape cassette, etc.) that record or store such software or computer programs. Exemplary embodiments are further intended to cover such software, computer programs, systems and/or processes provided through any other currently known, related art, or later developed medium (such as transitory mediums, carrier waves, etc.), usable for implementing the exemplary operations disclosed below.

In accordance with the exemplary embodiments, the disclosed computer programs can be executed in many exemplary ways, such as an application that is resident in the memory of a device or as a hosted application that is being executed on a server and communicating with the device application or browser via a number of standard protocols, such as TCP/IP, HTTP, XML, SOAP, REST, JSON and other sufficient protocols. The disclosed computer programs can be written in exemplary programming languages that execute from memory on the device or from a hosted server, such as BASIC, COBOL, C, C++, Java, Pascal, or scripting languages such as JavaScript, Python, Ruby, PHP, Perl, or other suitable programming languages.

As referred to herein, the terms “computing device” and “entities” should be broadly construed and should be understood to be interchangeable. They may include any type of computing device, for example, a server, a desktop computer, a laptop computer, a smart phone, a cell phone, a pager, a personal digital assistant (PDA, e.g., with GPRS NIC), a mobile computer with a smartphone client, or the like.

As referred to herein, a user interface is generally a system by which users interact with a computing device. A user interface can include an input for allowing users to manipulate a computing device, and can include an output for allowing the system to present information and/or data, indicate the effects of the user's manipulation, etc. An example of a user interface on a computing device (e.g., a mobile device) includes a graphical user interface (GUI) that allows users to interact with programs in more ways than typing. A GUI typically can offer display objects, and visual indicators, as opposed to text-based interfaces, typed command labels or text navigation to represent information and actions available to a user. For example, an interface can be a display window or display object, which is selectable by a user of a mobile device for interaction. A user interface can include an input for allowing users to manipulate a computing device, and can include an output for allowing the computing device to present information and/or data, indicate the effects of the user's manipulation, etc. An example of a user interface on a computing device includes a graphical user interface (GUI) that allows users to interact with programs or applications in more ways than typing. A GUI typically can offer display objects, and visual indicators, as opposed to text-based interfaces, typed command labels or text navigation to represent information and actions available to a user. For example, a user interface can be a display window or display object, which is selectable by a user of a computing device for interaction. The display object can be displayed on a display screen of a computing device and can be selected by and interacted with by a user using the user interface. In an example, the display of the computing device can be a touch screen, which can display the display icon. The user can depress the area of the display screen where the display icon is displayed for selecting the display icon. In another example, the user can use any other suitable user interface of a computing device, such as a keypad, to select the display icon or display object. For example, the user can use a track ball or arrow keys for moving a cursor to highlight and select the display object.

As referred to herein, a computer network may be any group of computing systems, devices, or equipment that are linked together. Examples include, but are not limited to, local area networks (LANs) and wide area networks (WANs). A network may be categorized based on its design model, topology, or architecture. In an example, a network may be characterized as having a hierarchical internetworking model, which divides the network into three layers: access layer, distribution layer, and core layer. The access layer focuses on connecting client nodes, such as workstations to the network. The distribution layer manages routing, filtering, and quality-of-server (QoS) policies. The core layer can provide high-speed, highly-redundant forwarding services to move packets between distribution layer devices in different regions of the network. The core layer typically includes multiple routers and switches.

In embodiments, systems and methods in accordance with the present disclosure can analyze and identify referential integrity issues for a DAG driven by multiple properties that are used to define the vertices and/or the edges. A system can determine what logical computational values may exist for each vertex based on relationships and rules with other vertices and the edges that connect those vertices. The system can also examine the absence of one or more key properties, out of range value for properties, and probabilistic risk items within the DAG.

In accordance with embodiments, a system can collect data on the issues identified above and relevant vertices related to the logical defects identified in the process described above so the referential integrity issue can be resolved through user intervention or the execution of automated communication and/or reconciliation to logical property values within the DAG.

In accordance with embodiments, a system can compute a graph integrity index score (GIX) to provide a univariate representation on the structural integrity and risk of the DAG. Utilizing of project management embodiment, the GIX score can provide a quick indication to reliability, integrity and risk surrounding the key output values of the DAG. In the illustrative example of project management, it can indicate the validity of the project plan's forecasted dates and resource requirements as well as resource conflicts.

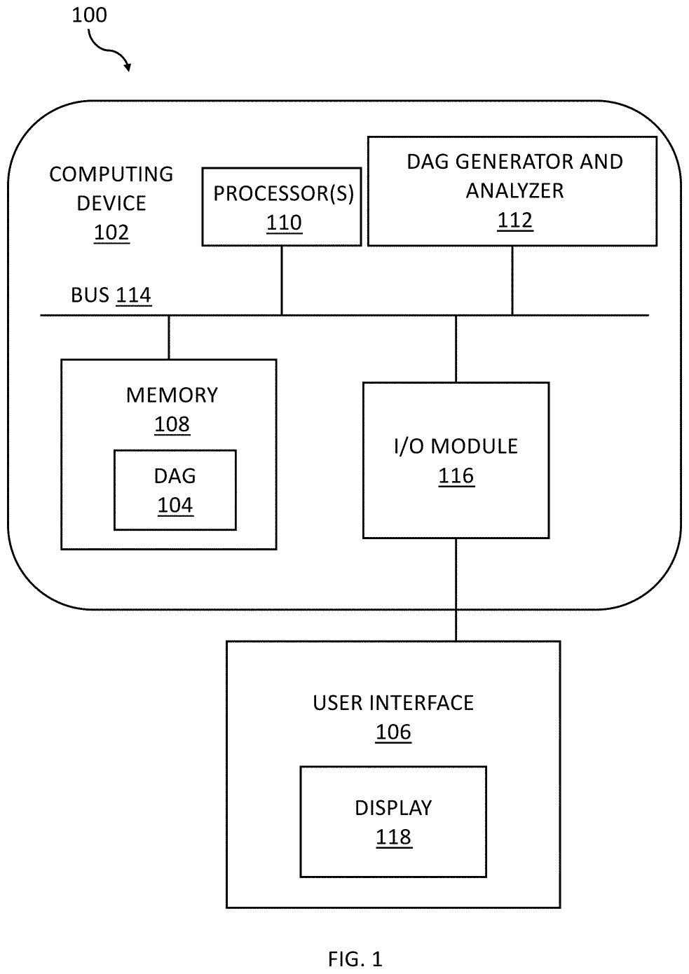

FIG. 1 illustrates a block diagram of system 100 including a computing device 102 configured to provide a DAG 104 representative of a project for management, to analyze properties of the DAG 104, and to present the analysis via a user interface 106 in accordance with embodiments of the present disclosure. Referring to FIG. 1, the computing device 102 includes memory 108 and one or more processors 110. A DAG generator and analyzer 112 can provide the DAG 104 in memory 108. Further, the DAG generator and analyzer 112 can be implemented by hardware, software, firmware, or combinations thereof. For example, the DAG generator and analyzer 112 can be implemented by the memory 108 and processor(s) 110. A bus 114 can operatively and communicatively connect the components of the computing device 102.

In accordance with embodiments, the DAG generator and analyzer 112 can provide, in the memory 108, the DAG 104. The DAG can include vertices and edges connecting the vertices. The vertices can represent tasks in a project for management. The edges can represent dependencies among the tasks. The DAG generator and analyzer 112 can also provide, for each vertex, one or more task properties capable of affecting a property of one of the vertex's successor vertices via an edge. The DAG generator and analyzer 112 can also analyze one or more properties of the vertices and the edge dependencies to characterize the task properties. Further, the DAG generator and analyzer 112 can present the analysis via the user interface 106.

The user interface 106 can be operatively connected to the computing device 102 by an input/output (I/O) module 116 of the computing device 102. More particularly, the DAG generator and analyzer 112 can control the I/O module 116 to output commands to the user interface 106 to present the analysis of the properties of the vertices and edge dependencies to characterize the task properties. In an example, the user interface 106 can include a display 118. The display 118 may be configured to present the analysis data in a suitable form for review by an operator. For example, the display 118 can present the data as text and/or in graphical form.

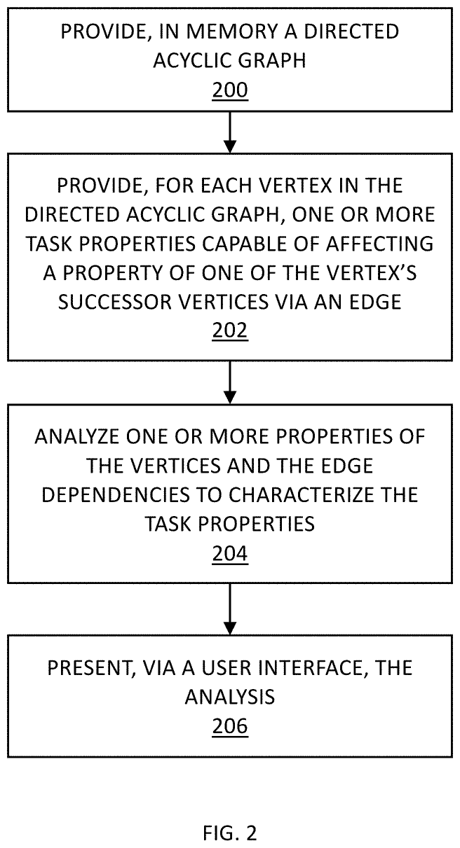

FIG. 2 illustrates a flow diagram of a method for providing a DAG representative of a project for management, analyzing properties of the DAG, and presenting the analysis via a user interface in accordance with embodiments of the present disclosure. It is noted that the method is described as being implemented by the computing device 102 and user interface 118 shown in FIG. 1, but it should be appreciated that the method may be implemented by any other suitable computing device along with a user interface.

Referring to FIG. 2, the method includes providing 200, in memory, a DAG including vertices and edges connecting the vertices. The vertices represent tasks in a project, and the edges represent dependencies among the tasks. For example, the DAG generator and analyzer 112 can provide the DAG 104 in memory 108. The DAG generator and analyzer 112 can construct the DAG 104 in memory 108 into any suitable data structure.

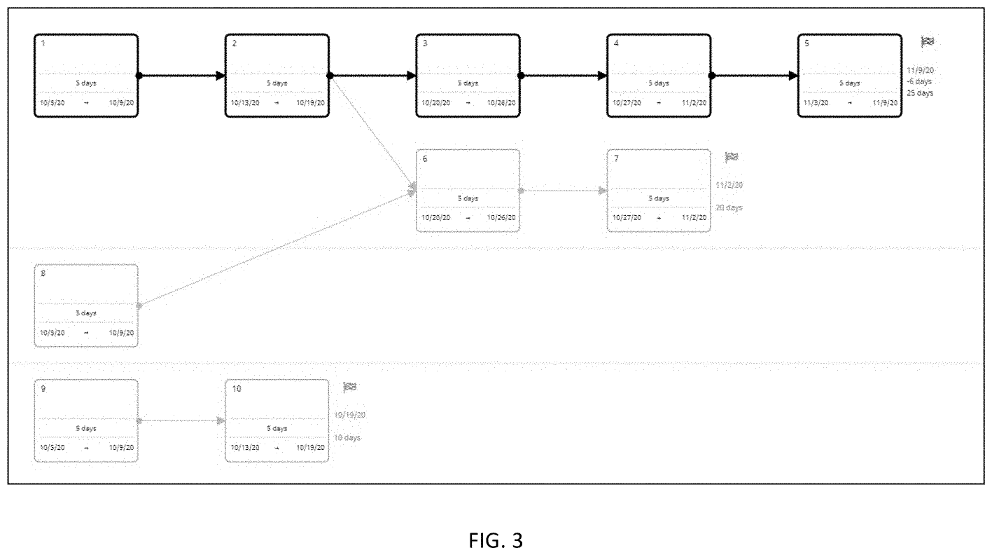

As an example of a DAG, FIG. 3 illustrates a schematic diagram of a DAG in the field of project management in accordance with embodiments of the present disclosure. The vertices represent tasks and the edges represent relationships between those tasks. In this example, the edges (relationships) have been defined as Finish-To-Start relationships. This means, the predecessor vertex (task) must have a status property value of “complete” prior to the initiation of the successor vertex (task).

Now referring again to FIG. 2, the method includes providing 202, for each vertex, one or more task properties capable of affecting a property of one of the vertex's successor vertices via an edge. Continuing the aforementioned example, the DAG generator and analyzer 112 can provide, for each vertex one or more task properties capable of affecting a property of one of the vertex's successor vertices via an edge of the DAG 104.

The method of FIG. 2 includes analyzing 204 one or more properties of the vertices and the edge dependencies to characterize the task properties. Continuing the aforementioned example, the DAG generator and analyzer 112 can analyze one or more properties of the vertices and the edge dependencies of the DAG 104 to characterize the task properties.

The method of FIG. 2 includes presenting 206, via a user interface, the analysis. Continuing the aforementioned example, the DAG generator and analyzer 112 can control the user interface 106 to present (e.g., display) the analysis data or information.

While this invention is applicable to many use cases, examples provided herein relate to project management. This use case embodies the challenges associated with corrupted, insufficient, and statistically risky DAGs and how the systems and methods disclosed herein can serve to identify, remediate and indicate aforementioned corruption, deficiencies and risks.

For the purposes of illustration, we will use the term “debug” to indicate the identification of a structural flaw with a DAG, an absent required property on a vertex, or a resource constraint conflict between vertices.

A DAG associated with a project plan generally possesses multiple tasks which are the vertices within the DAG. Those tasks can have a plurality of relationships to each other. Those relationships are the edges of the DAG. Those task dependency relationships (edges) can take four forms for example: Finish-to-Start, Finish-to-Finish, Start-to-Start and Start-to-Finish with the former-most being the most common and the latter-most being the least common in practice. Each dependency relationship (edge) in the DAG contains a property value to indicate a single predecessor vertex (task) and a single successor vertex (task). Each vertex (task) may contain a plurality of the task dependency relationships (edges). These project plan DAGs also can involve a computer system, and multiple methods for input and output of data into the computer system. These project plan DAGs can have one primary author/owner with a plurality of contributors and managers who are responsible for one or more vertices within the project plan DAG. A vertex (task) within the project plan DAG can have a plurality of properties to define work requirements and timelines within the project plan. Each vertex (task) can require the following properties to operate within the DAG correctly: start date, end date, duration. In addition to these required properties, the properties of task owner, work estimate and determination if the dates must be locked can also be critical for valid information to be derived from the project plan DAG. These properties can work in conjunction with the project plan edges (task dependency relationships), to determine the discrete math calculations so a determination of overall project duration and completion date can be identified.

In embodiments, there can be dependencies between multiple distinct disparate project plan DAGs. In the field of project management, these are referred to as inter-project dependencies. The project plan DAG of focus can be referred to as the Primary Project Plan (PPP) DAG and the related project plan DAGs can be referred to as the Secondary Project Plan (SPP) DAGs.

It is noted that with the advent of online collaboration between contributing entities, individual vertices (tasks) can be changed by contributors which invalidate the accuracy of the current project plan DAG resulting in flawed durations and dates. This introduces unnecessary risk to the project because it hides delays and potential risk. Furthermore, it typically requires significant experience and knowledge in the art of project management to identify said flaws and execute remediation. Untrained project managers cannot typically identify the structural flaws within a plan and are therefore unaware of the inaccuracy of the project plan DAG. This problem is only amplified when considering project plan DAGs that contain hundreds or thousands of tasks and the introduction of dependencies on projects outside of the primary project plan DAG. In these cases, even experience project managers cannot readily identify the critical flaws that may impact the accuracy of the project plan DAG.

For the presently disclosed subject matter, within the project management application, the properties of start and due date require two values: (1) the Current Property Values (CPV) what are user-input or previously existing values for start and due dates; and (2) the Logical Property Values (LPV). LPV are the mathematically accurate property values, in this case dates, according to the existing structure of the DAG and the plurality of date and time related properties associated with the task. Disparity between CPV and LPV is a common structural flaw within the project management embodiment of DAG debugging. LPV are additional broken out into Earliest Logical Property Value (E-LPV) and Latest Logical Property Value (L-LPV). In addition, the overall project DAG within the project management embodiment has two values for the completion date property. It has the Existing Forecast Date (EFD) and the Logical Forecast Date (LFD). The EDF is based on the CPV for the DAG and the LFD is based on the LPV for the DAG. A difference between these dates indicates logic flaws within the DAG.

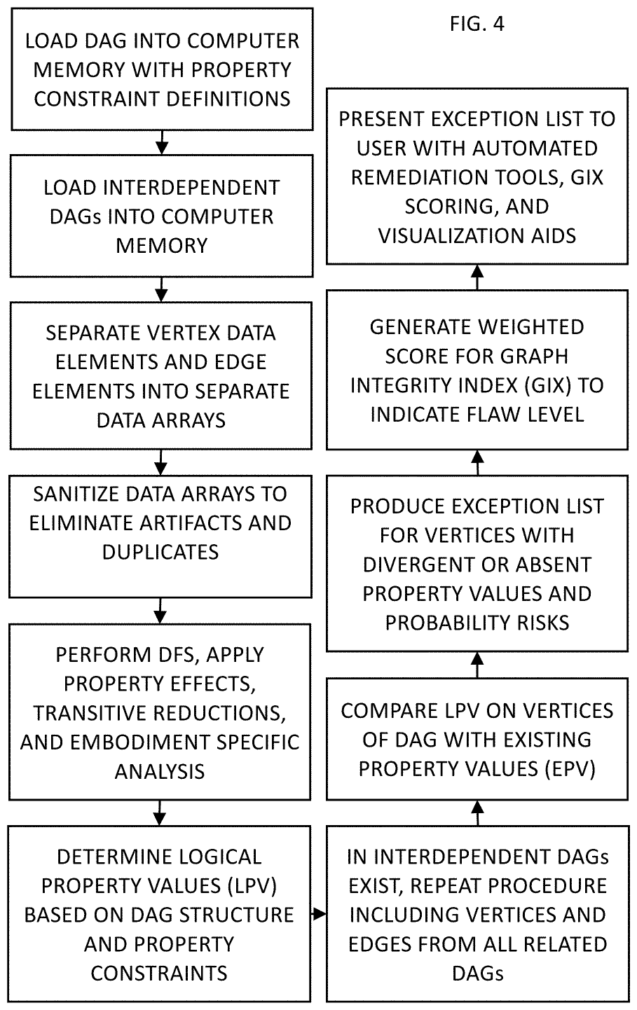

To automate the continuous identification of structural errors and deficiencies in sub-second performance for DAGs with a high plurality of vertices (tasks) and edges (dependency relationships), various steps may be applied. FIG. 4 illustrates a flow diagram of a method for continuous identification of structural errors and deficiencies in sub-second performance for DAGs with a high plurality of vertices (tasks) and edges (dependency relationships). It is noted that the method may be implemented by the computing device 102 and user interface 118 shown in FIG. 1, but it should be appreciated that the method may be implemented by any other suitable computing device along with a user interface.

FIG. 4 includes loading the PPP DAG into computer memory. For example, the DAG generator and analyzer 112 shown in FIG. 1 can load the DAG 104 into memory 108. Property constraint definitions may be included.

Optionally, FIG. 4 can including loading any SPP DAGs into memory. These are the interdependent separate DAGs to the PPP DAG. Continuing the aforementioned example, the DAG generator and analyzer 112 can load an SPP DAG into memory 108.

FIG. 4 also includes separating the vertices (tasks) and edges (relationships) into independent arrays of data objects. These will be referred to as the Vertex Data Object (VDO) array and Edge Data Object (EDO) array. Continuing the aforementioned example, the DAG generator and analyzer 112 can implement this functionality.

Subsequently, the EDO can be sanitized by ensuring that both predecessor and successor vertices (tasks) are present within the VDO and removing any duplicate edges (dependencies) that may exist within the EDO. Continuing the aforementioned example, the DAG generator and analyzer 112 can implement this functionality.

FIG. 4 includes identifying all EDO and VDO objects by their association with the PPP. This may be required if inter-DAG dependencies are present so accurate data property adjustments can be made to vertices (tasks).

Subsequently, the method includes iterating through each object of the VDO and create an attached data array containing a reference to all EDO objects that are related to that vertex (task).

Subsequently, a Property Constraint Definition (PCD) can be into computer memory for use in the DAG calculation process. The purpose of the PCD in the project management embodiment is to determine what dates are available for use within the DAG calculation process and how long said days are through a plurality property values that define said days. Continuing the aforementioned example, the DAG generator and analyzer 112 can implement this functionality.

For the embodiment of project management, standardized time units on task duration properties can be used across all vertices (tasks) for the DAG calculation process.

Subsequently, the system can determine the degree (i.e., count) value for both dependency and successor relationships (edges) for each vertex (task).

For the embodiment of project management, identify any vertices (tasks) in the VDO where the CPV properties are immutable. This frequently happens in projects where a task must occur on a specific date. For example, a conference, a building inspection, etc.

The method of FIG. 4 also includes sorting objects in the VDO by the predecessor quantity of EDO objects. There may be at least one VDO object with zero EDO objects or the graph is not a Directed Acyclic Graph. It is instead a Cyclic Graph and cannot be processed.

The method of FIG. 4 also includes conducting a depth first search (DFS) algorithm on all VDO objects. In the process of the DFS algorithm, identify any potential EDOs that create a cyclic graph within the DAG

The system can identify any late vertices (tasks) where the current date is later than the due date CPV. These vertices (tasks) can be marked as late within the VDO.

The method of FIG. 4 also includes determining the difference between the CPV and the current date for late tasks and apply this difference to the duration. For the embodiment of project management, the PCD can be utilized to determine the number of business days the vertex (task) is delayed. This difference may be applied to the duration of the late task so the effect of it being late can cascade down the project plan DAG in the computation of the LPV for each task. This can be an important step in ensuring a continually accurate DAG and identifying the current critical path within the project management embodiment. The critical path within a project management embodiment of a DAG is defined as the longest sequence of vertices (tasks) which must be completed on time. Critical paths within a project DAG can change frequently based on the change in key properties (dates) for the vertices (tasks). If the delay on a task exceeds its float as defined in float calculate below, the critical path can change to include the delayed task and increase the overall project duration.

The method of FIG. 4 also includes calculating the DAG model distance (i.e. duration) values based on the DFS in the preceding step. The distance (i.e. duration) can determine the length of the workstreams within the project management embodiment as well as identification of one or more critical paths.

Subsequently, the method of FIG. 4 can include applying a transitive reduction process on the DAG to reduce redundant relationships.

The method can include repeating the step of determining the difference between the CPV and the current date for late tasks and applying this different to the duration. This can include accommodating the immutable, or locked date properties, within the vertices (tasks) for the project management embodiment. This step can be important because it can help identify induced lags in the project plan DAG. Lag in the project management embodiment is where the latency of a task dependency (edge relationship) has increased duration. It is noted that this virtual lag is different from the defined traditional lag in the project management embodiment where a successor vertex (task) must have a required gap between conclusion of the predecessor and instantiation of the successor vertex (task).

The method can also include sorting the VDO array by total distance calculated in the prior step. The longest duration object, or objects, in this sort will become the last task within the critical path.

The method can include recursively moving forward through each vertex with no incoming edges (task dependencies) to calculate each individual successor E-LPV. Each recursion and the LPV assigned to the vertex (task) can be dependent on both the edge relationship (task dependency) and the time span the duration covers and its interaction with the PCD defined in the step of loading a PCD. During this process, one or more vertices (tasks) may be visited multiple times because each successive task can be connected via a plurality of predecessors. Only LPV that are later than existing LPV should be propagated within the DAG. If the user identifies that a project timeline should be compressed (i.e. shortened) if a vertex (task) has it status property given a value of “completed” prior to the CPV for due dates, then the task completion date should be used in lieu of the LPV for due date. For the purpose of managing LPV with Interproject Dependencies (IPD), mark the LPV values without the influence of IPD. LPV may only be changed if the IPD influenced LPV is later than the LPV generated by the first pass calculation with only the Primary Project Plan (PPP).

The method includes recursively moving backward through each vertex with a duration equal to the maximum duration of a path that traverses the DAG to mark the vertices (tasks) that are on the critical path.

Further, the method includes recursively moving backwards through each vertex with no outgoing edges (task dependencies) to calculate each individual predecessor L-LPV.

Further, the method includes recursively moving backwards through each vertex with no outgoing edges (task dependencies) to calculate the difference between the E-LPV and the L-LPV. This value is known in the project management embodiment as float. It represents the time before an individual task will become part of the critical path on a project management DAG.

Repeat the process outlined in step 17 utilizing the virtual lag values generated in step 15. These will represent the final LPV for the vertices (tasks).

Optionally, the method can include consolidating any VDOs and EDOs of other separate independent project plan DAGs where a dependency exists. If VDOs and EDOs have been consolidated into the primary EDO and VDO, conduct a continual regression process consolidating all VDOs and EDOs of all inter-dependencies that exists throughout the complete chain of interdependencies between DAGs.

The method includes repeating the process outlined above, excluding the previous two steps, to produce accurate LPV that accommodates all inter DAG dependencies and resource constraints.

Further, the method includes identifying defects, omissions, capacity conflicts and probabilistic risk, (DAG issues) in the project DAG. the final VDO array can be processed for all combined projects in the case of IDP projects, or the standalone VDO for a single project DAG. For the embodiment of project management, a plurality of criterion exists for logic flaw detection, key data omission and resource conflict identification. These criterion can include, but are not limited to, the following:
a. Identification of all vertices (tasks) where the duration is missing, this indicates that the overall duration and forecast dates are unreliable because duration is seen as a required property to produce date forecasts and resource conflicts.
b. Identification of all vertices (tasks) where the work estimate is missing, this indicates that the overall duration and forecast dates are unreliable because duration is seen as a required property to produce date forecasts and resource conflicts. In addition, work estimates must reconcile with the duration. For the project management embodiment, it is not considered possible to perform 40 hours of a work estimate within a duration of one day. This is seen as a logical flaw. In addition, work estimates are required to determine where resource conflicts exist within the project management DAG.
c. A low ratio of tasks to dependencies within the DAG. This typically indicates incomplete definition and an unreliable date forecast.
d. Identification of all tasks that are currently late. These will provide LPV for start and due dates that are divergent from the CPV for all vertices (tasks) downstream of the late vertex (task). This renders the Existing Forecast Date (EFD) inaccurate. Additionally, tasks marked as milestones that are late are marked as such.
e. All vertices (tasks) with a status property of “blocked” are identified. In the project management embodiment, blocked status is an indication by the task owner or project manager that completion or execution of the task has been delayed or halted. If the block is not resolved, the task can become late and delay the project duration.
f. All tasks where the CPV is different than the LPV. When the CPV for start and due dates on tasks within a project DAG are inaccurate, the existing dates provide inaccurate start and completion times. This prevents accurate resource forecasting and renders the existing completion date for the project inaccurate in many cases.
g. All tasks where the dates are marked as “locked” where the CPV is different than the LPV are marked separately. In the previous item, CPV can be updated to the LPV when the project is recast with the accurate model. However, if a task with locked dates has inaccurate CPV and those values are prior to the LPV, then the LPV indicates that the locked dates are in jeopardy.
h. All tasks where the status property is marked “complete” while a predecessor task has a status property marked “incomplete”. It is illogical in the project management embodiment for a predecessor task to be incomplete while the successor task is complete.
i. All tasks with excessive durations are marked. Tasks with excessive durations are indicators of incomplete project plan DAG definition and increase risk. 9.
j. All independent DAGs within the overall PPP are identified. Multiple distinct DAGs within a project management embodiment indicate fragmentation of the plan and typically denote incomplete project plan definition which decreases forecast accuracy. 4.
k. All tasks are marked where there is capacity conflict for an assigned resource. This occurs when a resource is expected to complete a plurality of tasks within the same timeframe that requires a total work sum that exceeds the available duration. 8.
l. All tasks are marked where there is insufficient remaining duration to complete the required work on a task. This is based on the current date in relation to the CPV due date.
m. All tasks that are marked as milestones that have an LPV that are later than the CPV are marked to indicate project delay risk for milestones.
n. All tasks with a high plurality of predecessor tasks are marked to determine probabilistic risk of on-time instantiation of task. A significant number of predecessor tasks has a strong correlation to delay according the to the expected values theorem.
o. All tasks that have not been marked as accepted by the owner are marked. This indicates a lack of communication on a task and increases the risk of delay

The method also including taking all DAG issues identified in the prior step and presenting to the user via a computer UI/UX. This debugging view can show the number of tasks affected by the DAG issues and allow for user interaction to isolate those affected tasks for remediation.

The method includes providing a UI/UX mechanism for the user to isolate and view DAG Issues interactively. This can be done with three different viewing options: (1) view the tasks associated with DAG Issue in full context of all other tasks; (2) view the tasks associated with the DAG issue with the DAG issue tasks highlighted while still in context of other tasks; and (3) view the DAG issue with the only the DAG issue tasks visible but still in the logical context of the topological sort of the DAG.

Create a univariate score based on all issues created during the step of identifying defects, omissions, capacity conflicts, and probabilistic risk. This univariate score is constructed by assessing penalties from a plurality of criterion with each criterion having a weighted value based on the industry use case. The penalty values can follow linear decays and sigmoid, logistic decays based on the optimized simulation for the effect of the defect and its ability to predict risk. The total value of all penalties is combined and applied to a compound, exponential decay function to indicate the degradation of integrity in the DAG.

The method also includes providing a UI/UX mechanism to review each DAG issue in the proper sequence. This AI remediation agent can present a plurality of issues individually. Each issue can be presented with a commonly understood tag, the risk it presents by existing in the DAG and the possible remediation steps to improve the integrity of the DAG. The UI/UX mechanism can provide the ability to directly edit the tasks associated with the DAG issue in a view that excludes the non-affected tasks. Options can also be presented to allow the user to show some or all the other non-affected tasks in context with the affected tasks. As remediation occurs, the univariate score previously calculated can adjust according to the remediation enacted by the user's direct editing of the tasks or execution of automation functions provide for bulk remediation of affected tasks.

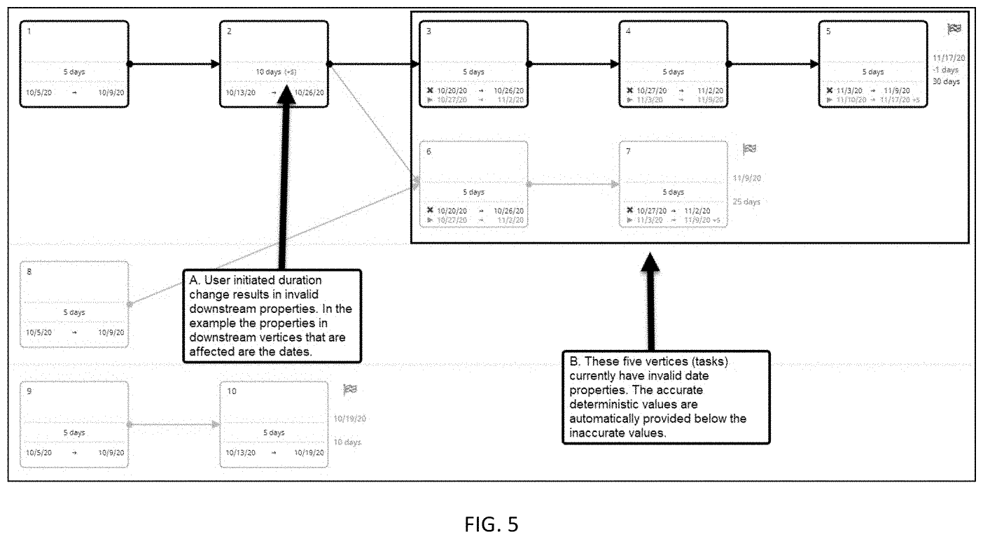

FIG. 5 illustrates a schematic diagram of a DAG showing a mathematically inaccurate property within the DAG. In the example shown, the duration for vertex 2 (task 2), has been modified from its original value and has created illogical values for date properties in downstream vertices (tasks) within the DAG based on the discrete math calculations.

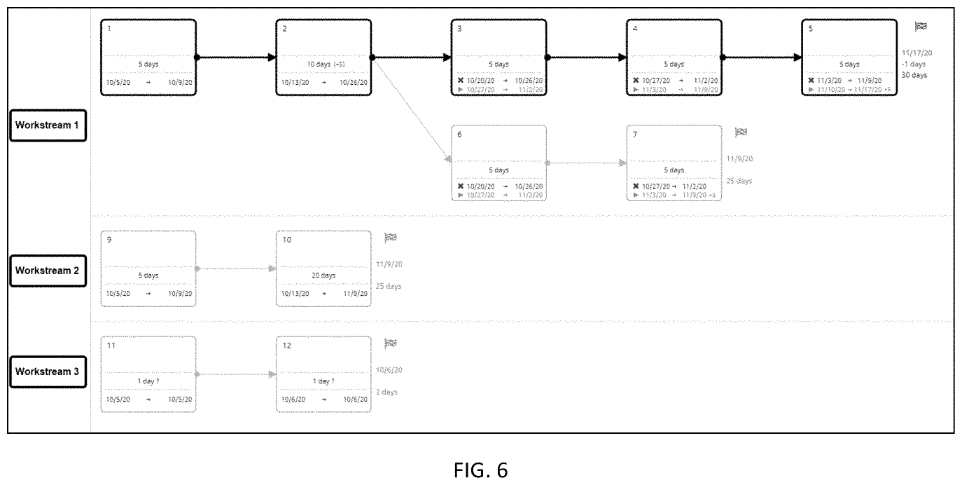

FIG. 6 illustrates a schematic diagram of a DAG showing fragmentation within the DAG. In the field of project management, fragmentation is typically an indication of incomplete DAG definition.

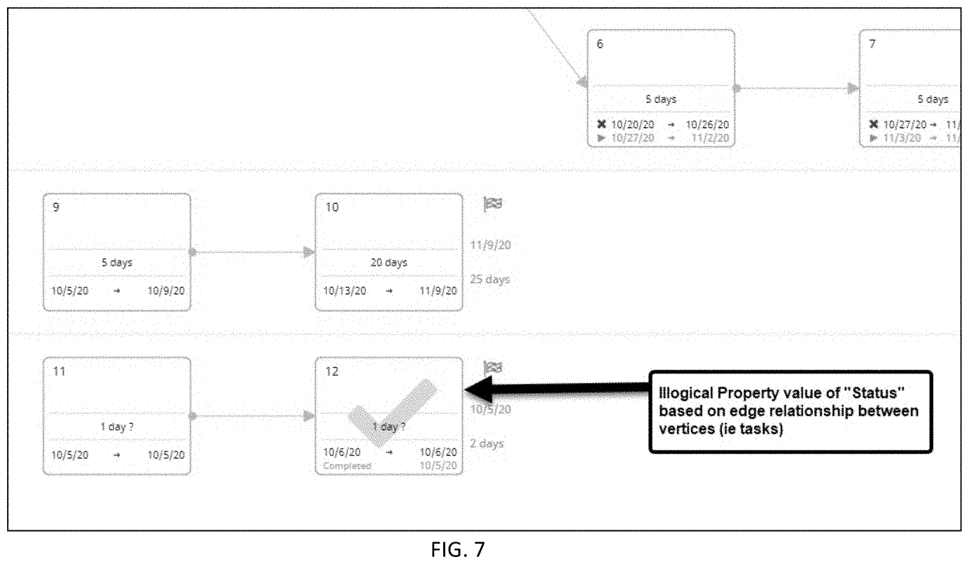

FIG. 7 illustrates a schematic diagram of a DAG showing an illogical property value within the DAG. In the example show, the property of “task status” is show as complete in task 12 while the property of “task status” is still incomplete in the predecessor vertex (task 11). Within the field of project management, with a Finish-To-Start edge (relationship), successors cannot be marked as complete while predecessors remain incomplete.

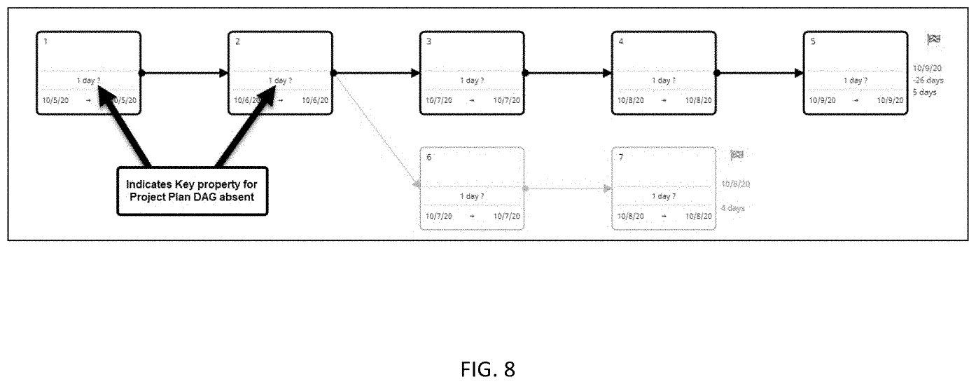

FIG. 8 illustrates a schematic diagram of a DAG with a missing required property for the DAG definition. In the field of project management, the property of duration is a required property for accurate date property forecasting within a DAG definition.

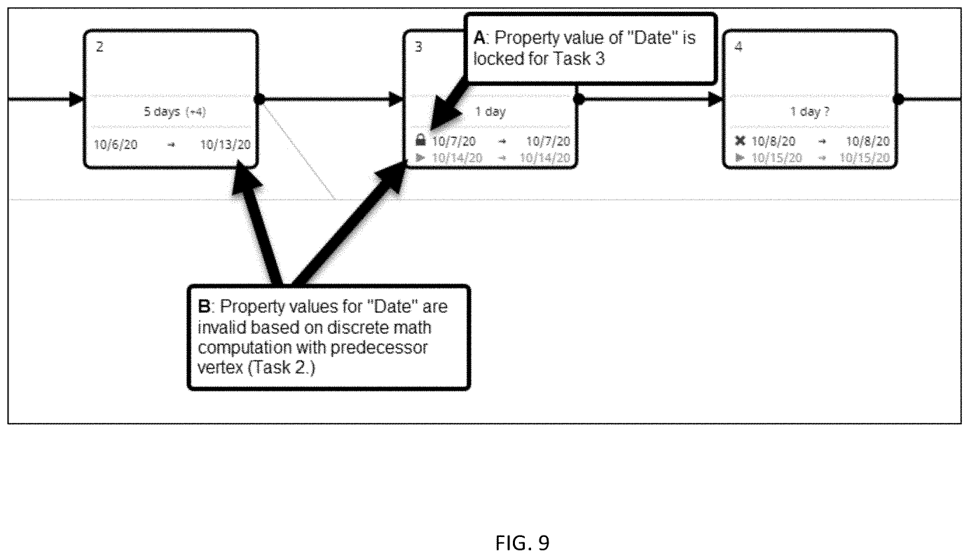

FIG. 9 illustrates a schematic diagram of a DAG with an inaccurate immutable property within the DAG definition. In the field of project management, certain vertices (tasks), are required to have properties that do not change. A common example is a task that must occur on, or within a specified date range (e.g. a building inspection).

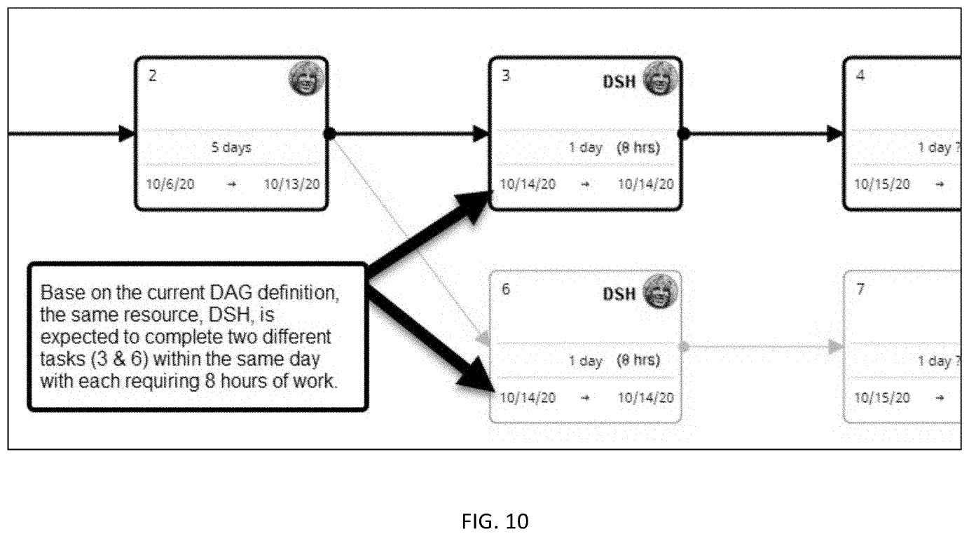

FIG. 10 illustrates a schematic diagram of a DAG with a property constraint violation within the DAG definition. In the field of project management, vertices (tasks) are assigned to resources (task owner) for completion. If the same “resource” property is assigned to two different vertices (tasks), if the “date” properties of those vertices (tasks) overlap in conjunction with a “work requirement” property that is functionally related to the “date” property, a situation may arise where there is insufficient quantity of the property “work requirement” for the “resource” identified.

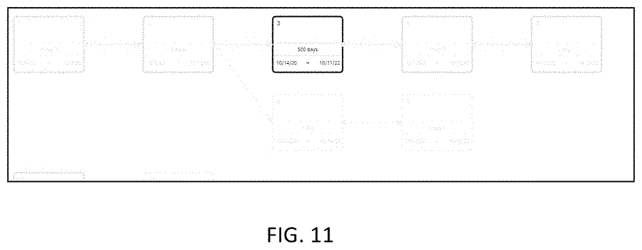

FIG. 11 illustrates a schematic diagram of a DAG with a vertex property with a value that exceeds best practice for the type of DAG use case. In the example provided, the property under evaluation is “task duration” in the project management embodiment. Excessive task durations are shown to increase forecast inaccuracy and risk because they frequently hide other relationships or sub-projects.

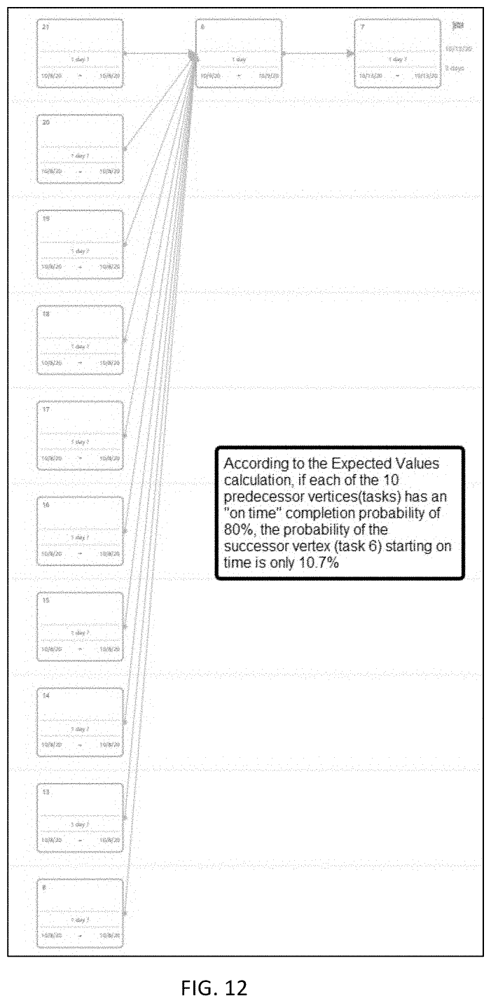

FIG. 12 illustrates a schematic diagram of a DAG with increased probabilistic risk based on statistical modeling of the relationships between vertices within the DAG. In the example provided, the probability of “on-time” initiation of the successor vertex (task 6) is dependent on the “on-time” completion of the 10 predecessor vertices (tasks). The probabilistic modeling can be completed either through the application of the expected values summation method. Or, it can be computed through Monte Carlo simulations utilizing a plurality of iterations to develop normalized distribution curves for propagation of property values through the DAG.

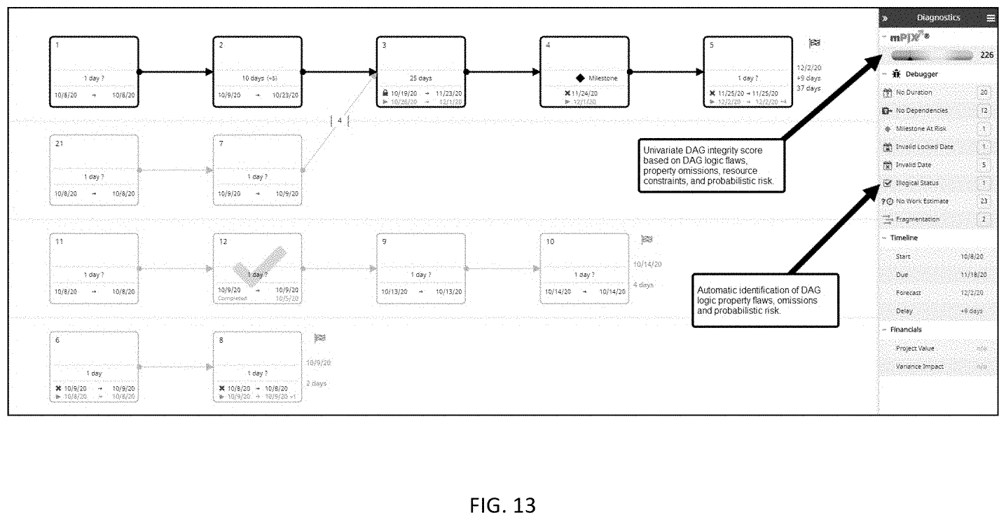

FIG. 13 illustrates a schematic diagram of a flawed DAG within the project management embodiment. Also present in the diagram is the DAG debugger. Its purpose is for automatic identification of the logic flaws, absent properties, resource constraints and probabilistic risk. Also present in the diagram is a univariate score (GIX) that serves as a predictor of overall DAG integrity and risk. In the example provides, the project management embodiment, the score would indicate the ability of the DAG to accurately forecast dates and understand resource constraints.

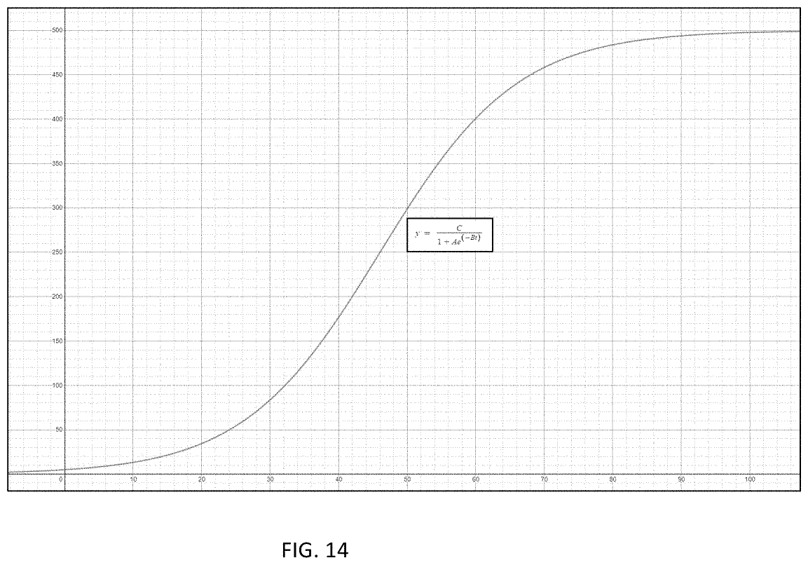

FIG. 14 illustrates a graph with a sigmoid, or logistic growth curve, representing non-linear response to a component penalty associated with logic flaws, absent properties, resource constraints and probabilistic risk within a DAG.

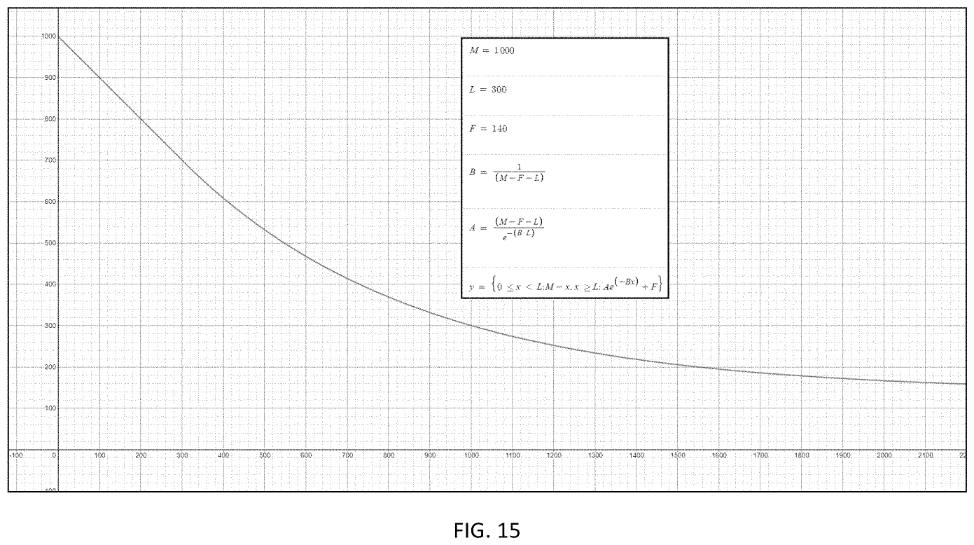

FIG. 15 illustrates a graph with a composite, nonlinear decay function to describe the degradation of the graph integrity index (y axis) from a maximum score and an asymptotic approach to a pre-defined floor value. The x-axis represents total penalties accumulated for logic flaws, absent properties, resource constraints and probabilistic risk within a DAG.

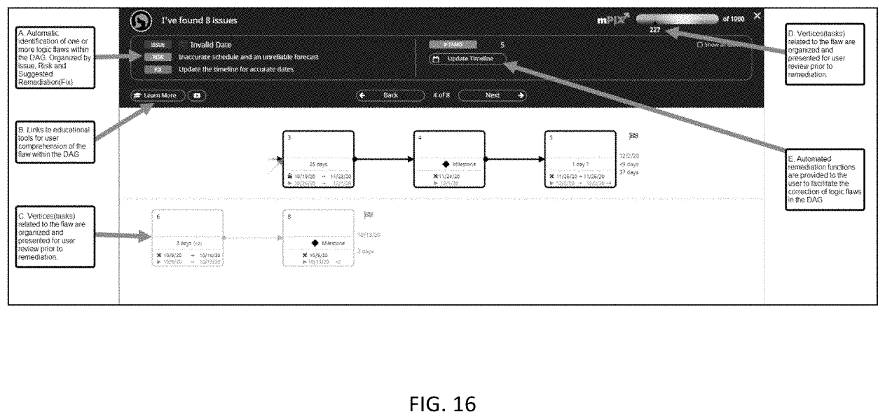

FIG. 16 illustrates a diagram of a computer-agent-directed remediation of a DAG for one or more logic flaws it may contain. The diagram illustrates flaw identification, description, remediation process. Additionally, it depicts curation of the flawed vertices (tasks) for the project management industry example, links to educational material related to the flaw or risk, a univariate integrity score to gauge accuracy and risk in the DAG as well as access to one or more remediation functions.

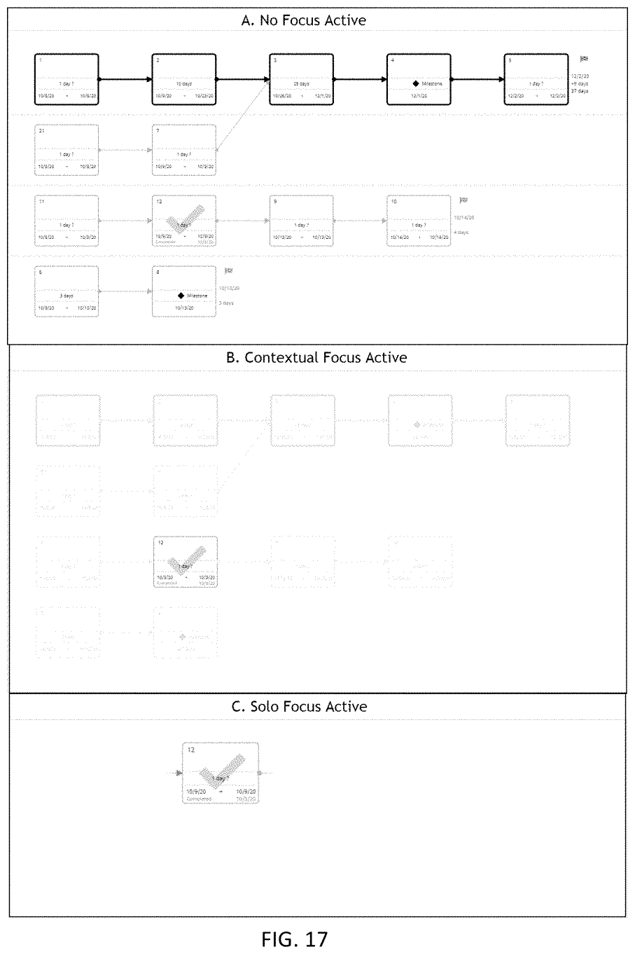

FIG. 17 illustrates a diagram representing multi-stage, dynamic identification and display of one or more areas of interest within a DAG. In the example provided, an illogical property “status” for a vertex (task) is the area of interest with the project management embodiment.

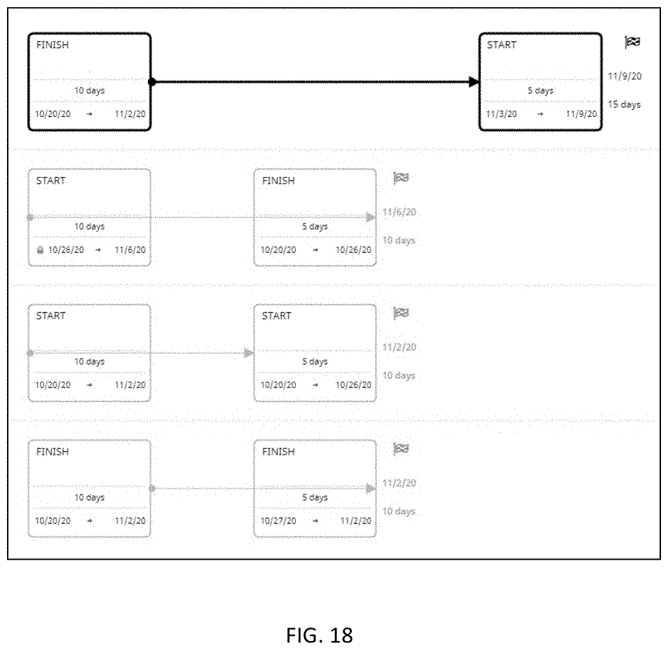

FIG. 18 illustrates a diagram depicting edge types within the DAG for the project management embodiment.

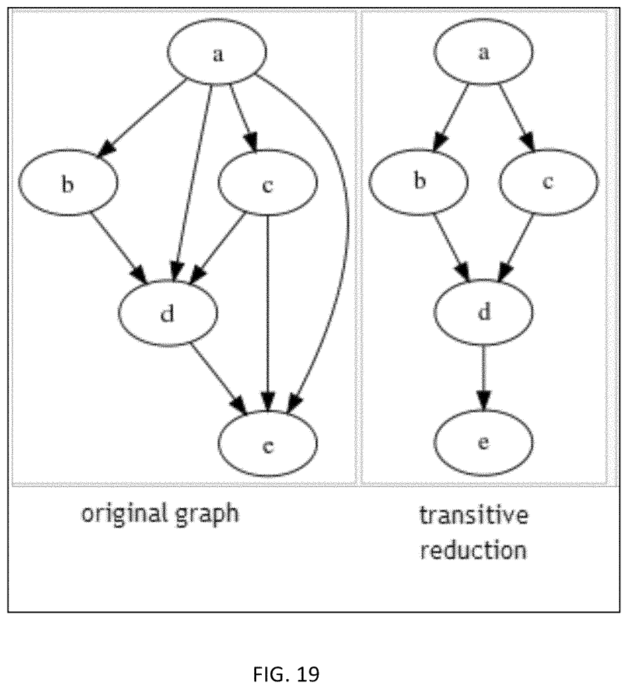

FIG. 19 illustrates a diagram depicting transitive reduction of a DAG.

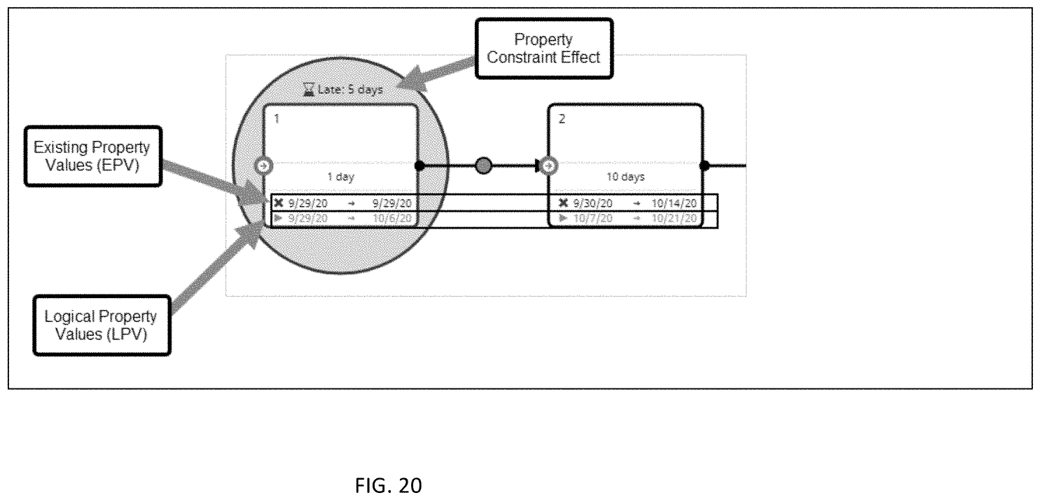

FIG. 20 illustrates a diagram depicting Current Property Values (CPV), Logical Property Values (LPV) and property constraint impacts on a DAG in the project management embodiment.

The present subject matter may be a system, a method, and/or a computer program product. The computer program product may include a computer readable storage medium (or media) having computer readable program instructions thereon for causing a processor to carry out aspects of the present subject matter.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a RAM, a ROM, an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network, or Near Field Communication. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present subject matter may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Java, Smalltalk, C++, Javascript or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present subject matter.

Aspects of the present subject matter are described herein with reference to flowchart illustrations and/or block diagrams of methods, apparatus (systems), and computer program products according to embodiments of the subject matter. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present subject matter. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the embodiments have been described in connection with the various embodiments of the various figures, it is to be understood that other similar embodiments may be used, or modifications and additions may be made to the described embodiment for performing the same function without deviating therefrom. Therefore, the disclosed embodiments should not be limited to any single embodiment, but rather should be construed in breadth and scope in accordance with the appended claims.

What is claimed is:

1. A method comprising:
at a computing device comprising memory and at least one processor:
providing, in the memory, a directed acyclic graph including a plurality of vertices and a plurality of edges connecting the vertices, wherein the vertices represent tasks in a project, and wherein the edges represent dependencies among the tasks;
providing, for each vertex, at least one task property capable of affecting a property of one of the vertex's successor vertices via an edge;
analyzing one or more properties of the vertices and the edge dependencies to characterize the task properties; and
presenting the analysis via a user interface.

2. The method of claim 1, further comprising receiving data of the project for the task properties.

3. The method of claim 1, wherein analyzing comprises:
applying at least one testing criterion to the directed acyclic graph; and
determining an integrity characteristic of at least one of the properties based on the applied at least one testing criterion.

4. The method of claim 1, further comprising:
receiving data for updating a task property of one or more of the vertices;
re-analyzing the one or more properties of the vertices and the edge dependencies to characterize the task properties based on the update; and
presenting the re-analysis via the user interface.

5. The method of claim 1, further comprising preparing the directed acyclic graph by application of one of a sanitization technique, depth first sort analysis, transitive reduction, delays for project management, immutable properties for project management, and dynamic critical path identification.

6. The method of claim 1, further comprising generating a set of logical property value properties for the project separate from the current property value properties for the project for producing a mathematically accurate date propagation through the directed acyclic graph independent of existing date properties.

7. The method of claim 6, further comprising generating a set of forecasted date values separate from the current forecasted date values.

8. The method of claim 1, further comprising identifying vertices that one of cause or affected by insufficient data on key vertex properties.

9. The method of claim 1, further comprising identifying vertices that one of cause or affected by overlapping resource constraint related properties.

10. The method of claim 1, further comprising identifying vertices that have high probabilistic risk to downstream vertices.

11. The method of claim 1, wherein presenting the analysis comprises electronically notifying one or more users about issues with the directed acyclic graph.

12. The method of claim 1, wherein analyzing comprises generating a weighted univariate value to indicate accuracy of integrity of the directed acyclic graph.

13. The method of claim 1, wherein analyzing comprises assigning a weighted value for individual directed acyclic graph issues that follow a non-linear decay function.

14. A system comprising:
a computing device including memory and at least one processor that implements a directed acyclic graph (DAG) generator and analyzer configured to:
provide, in the memory, a directed acyclic graph including a plurality of vertices and a plurality of edges connecting the vertices, wherein the vertices represent tasks in a project, and wherein the edges represent dependencies among the tasks;
provide, for each vertex, at least one task property capable of affecting a property of one of the vertex's successor vertices via an edge; and
analyze one or more properties of the vertices and the edge dependencies to characterize the task properties; and
a user interface configured to present the analysis.

15. The system of claim 14, wherein the DAG generator and analyzer is configured to:
apply at least one testing criterion to the directed acyclic graph; and
determine an integrity characteristic of at least one of the properties based on the applied at least one testing criterion.

16. The system of claim 14, wherein the DAG generator and analyzer is configured to:
receive data for updating a task property of one or more of the vertices; and
re-analyze the one or more properties of the vertices and the edge dependencies to characterize the task properties based on the update; and
wherein the user interface is configured to present the re-analysis.

17. The system of claim 14, wherein the DAG generator and analyzer is configured to prepare the directed acyclic graph by application of one of a sanitization technique, depth first sort analysis, transitive reduction, delays for project management, immutable properties for project management, and dynamic critical path identification.

18. The system of claim 14, wherein the DAG generator and analyzer is configured to generate a set of logical property value properties for the project separate from the current property value properties for the project for producing a mathematically accurate date propagation through the directed acyclic graph independent of existing date properties.

19. The system of claim 14, wherein the DAG generator and analyzer is configured to electronically notify one or more users about issues with the directed acyclic graph.

20. The system of claim 14, wherein the DAG generator and analyzer is configured to generate a weighted univariate value to indicate accuracy of integrity of the directed acyclic graph.
